(19) United States
(12) Patent Application Publication
(10) Pub. No.: US 2024/0059565 A1
(43) Pub. Date: Feb. 22, 2024

(54) ULTRATHIN NANORIBBONS OF HIGHLY ANISOTROPIC LAYERED MATERIAL AND METHOD OF PRODUCTION

(71) Applicant: University of Louisville Research Foundation, Inc., Louisville, KY (US)

(72) Inventors: Jacek B. Jasinski, Louisville, KY (US); Hui Wang, Beijing (CN); Gamini Sumanasekera, Louisville, KY (US); Usman Abu, Abuja (NG); Sharmin Akter, Dhaka (BD)

(21) Appl. No.: 18/450,060

(22) Filed: Aug. 15, 2023

Related U.S. Application Data
(60) Provisional application No. 63/398,020, filed on Aug. 15, 2022.

(51) Int. Cl. C01B 25/00; H01L 29/06; B82Y 40/00

(52) U.S. Cl. CPC C01B 25/003; H01L 29/0673; B82Y 40/00; C01P 2004/17; C01P 2004/64; C01P 2006/40

(57) ABSTRACT

Black phosphorous (BP) flakes are nanostructured via electrochemical intercalation of Na⁺ ions into bundles of phosphorene nanoribbons (PNRs). The large diffusion barrier of Na⁺ ions along the armchair direction leads to a well-defined columnar intercalation of Na⁺ ions in BP, resulting in the long zigzag-oriented columns of disordered material. The sonication of the bundles is then used to separate the PNRs.

### GOVERNMENT SUPPORT

This invention was made with government support under grant number DE-SC0019348 awarded by the Department of Energy. The government has certain rights in the invention

### FIELD OF THE INVENTION

Aspects of the invention pertain to ultrathin nanoribbons of highly anisotropc layered material, and particularly to phosphorene nanoribbons.

### BACKGROUND

The emergence of 2D materials and the rapid development of this field in the last two decades has led to a whole new class of structures with extraordinary physical, electronic, optical, and chemical properties as well as new applications in technologies such as electronic, sensors, catalysis, energy storage, environmental science, biomedicine, etc. While 2D materials confine charge carriers to a plane, one-dimensional (1D) structures, such as nanowires and nanoribbons (NRs), localize carriers in one more dimension which leads to additional unique properties, including higher mobility, strain tunable characteristics, high optical absorption, high density of states, enhanced excitation binding energy, improved surface scattering for electrons, etc.

### SUMMARY

Phosphorene nanoribbons, which are fully or predominantly crystalline phosphorous in character, and which are ultrathin (e.g., 50 nm or less in width and most preferably 1 to 15 or 20 nm in width), are prepared by a methodology wherein black phosphorous flakes or grains are nanostructured into bundles of parallel phosphorene nanoribbons separated by regions of disordered phosphorous. An exemplary method of producing these bundles involves intercalating of sodium or other cationic ions (e.g., calcium, silver, hydronium, ammonium, ferrous, ferric, etc.) into the structure of the black phosphorous, preferably by using electrochemical processing. The regions of disordered phosphorous may include sodium or other ions which are intercalated into the black phosphorus flakes to produce black phosphorus. The bundles of parallel phosphorene nanoribbons can then be separated into a plurality of individual phosphorene nanoribbons preferably by sonication in a solvent, such as dimethyl formamide (DMF). The sonication process and the solvent both separates the individual phosphorene nanoribbons and removes the disordered phosphorous regions. Despite the ultrathin nature of the phosphrene nanoribbons, the phosphorene nanoribbons can have lengths ranging from 1 to 10,000 nm, and are preferably 50 nm to 200, 300, 400, 500 nm, 600 nm, 700 nm, 800 nm, 900 nm, 1000 nm, 1200 nm, 1500 nm, 2000 nm, 3000 nm, 4000 nm, 5000 nm or 10,000 nm in length.

NRs also have high concentration of edge sites, which are often responsible for excellent catalytic performance and allow an easy functionalization and further tuning of properties toward high performance applications in fields such as energy storage, hydrogen generation, sensors, etc. In addition, properties of NRs can also be further modified through various other means, such as doping, defects, strain, size, morphology, phases, intercalation, etc. Besides energy applications, NRs can also serve as key building blocks of quantum technologies. NRs of topological insulators (TIs) can display exotic properties and be used for novel quantum devices. NRs can also exhibit magnetic or superconducting behavior like in the case of zigzag phosphorene NRs (ZPNRs) where electronic properties have been shown to be dominated by four degenerate quasi-flat edge bands. Superconductor-based quantum effects, such as the Josephson effect and crossed Andreev reflection have recently been investigated in structures based on such nanoribbons. ZPNRs are also predicted to host a number of other exotic states and can play an important role in several fundamental areas of condensed matter physics. In addition to topologically-protected edge states, some of the other exotic properties predicted for these structures include spin-density waves, strain-dependent antiferromagnetism, and half-metallic behavior which could be relevant to spintronics applications, the spin-dependent Seebeck effect, that could help to advance thermoelectric technologies, and a large singlet-triplet spitting, that could potentially be relevant to quantum information.

To fully utilize the unique properties of NRs and to develop novel NR-based devices, reliable fabrication methods for producing NRs with controlled structures and desired properties are needed, and this invention specifically provides for improved fabrication methods as well as ultrathin NRs that have not been produced by any means before.

Some aspects of this invention provide a novel electrochemical method for the fabrication of NRs of highly anisotropic 2D materials via a series of in situ and ex situ techniques. In an embodiment of this method, alkali metal ions are inserted electrochemically into an anisotropic layered van der Waals (vdW) material and in the process, they nanostructure it into bundles of parallel NRs. A subsequent sonication treatment is used to separate the nanostructured bundles into individual well-isolated NRs. Embodiments of the invention can be focused on 2D materials with a puckered honeycomb structure, especially alpha-phase allotropes of group V-elements and group-IV monochalcogenides. These materials exhibit unique properties and are predicted to exhibit quantum phases. Electrochemical insertion of Na-ions into bulk black phosphorous (BP) was employed in embodiments of the invention, and successfully produced highly uniform PNRs with widths significantly narrower than in most previous works based on other methods. Certain embodiments of the invention are demonstrate that above a certain critical concentration of Na-ions, the electrochemical process leads to the formation of highly disordered phosphorous regions along the zigzag (ZZ) direction. These disordered regions are uniformly distributed between crystalline NR regions.

An exemplary synthesis process described herein utilizes the anisotropic ion diffusion in highly anisotropic two-dimensional (2D) materials. This methodology may be used for the fabrication of ultra-narrow phosphorene nanoribbons (PNRs). Electrochemically-driven Na-ion diffusion in black phosphorous (BP) was utilized for an embodiment of this process. The diffusion barrier for Na-ions in BP along the zigzag direction is much lower than that for the diffusion along the armichari direction, allowing production of zigzag-oriented PNRs with uniform morphology (width of 10 nanometer and length of 1 micrometer). Such ultranarrow PNRs has utility in, for example, electronic and optoelectronic applications, such as field-effect transistors, sensors as well as catalysts, etc.

Phosphorene nanoribbons with confined width and uniform length are demonstraged to be synthesized via a two-step electrochemical process. The produced PNRs show a significantly confined structure with the suppressed B2g vibrational mode, as revealed by Raman spectroscopy. Furthermore, unlike in the case of phosphorene or BP devices, a field effect transistor (FET) prepared from a bundle of our unseperated PNRs exhibits the typical n-type behavior.

Embodiments of the inventive synthesis method is more economic, straightforward, and scalable for large-scale production of nanoribbons. In addition, the produced PNRs have much narrower width than PNRs in most previous reports and other methods (electro-beam sculpting, electron-beam lithography, etching). The narrower widths of PNRs permit the PNRs to display more impressive properties (e.g. increase bandgap, modified electronic structure, higher density of states, etc.) due to quantum confinement effects, and high density of edge sites. In addition, narrow PNRs, like those described here, have excellent properties like polarization dependent anisotropic response, exceptional mechanical properties, and highly active bonding sites. Quantum confinement and diminished dielectric screening causes excitons in atomically thin semiconductors like PNRs to exhibit binding energies an order of magnitude larger than their bulk counterpart.

The synthesis method may be applied for producing ribbons from other highly anisotropic layered materials (e.g., selenophophate (AgSbP₂Se₆); arsenic trisulfide (As₂S₃); tin selenide (SnSe); etc.). Ideal materials would be highly anisotropic layered van der Waals materials such as a layered alloy of group V element, or a layered material of group IV monochalcogenides. The methodology has application to layered material with a puckered honeycomb structure. In some: embodiments, the methodology can be applied to an arsenic-phosphorous alloyed material where the relative molar concentration of arsentic to phosphorous is between 0 and 1. The nanoribbons produced by the inventive methology will have a length ranging from 1 nm to 10000 nm and a width ranging from 1 to 100 nm. Common to the methods of making nanoribbons from highly anisotropic layered materials would be nanostructuring one or more flakes or grains of highly anisotropic layered material using an electrochemical process of insertion of ions to produce bundles of nanoribbons separated from each other by regions of disordered materials; and ultrasonically treating the bundles of nanoribbons in a solvent medium in order to separate the bundles of nanoribbons into a plurality of separate nanoribbons.

### DESCRIPTION OF THE DRAWINGS

The patent or application file contains at least one drawing executed in color. Copies of this patent or patent application publication with color drawings will be provided by the Office upon request and payment of the necessary fee.

FIGS. 1(a)-(h). Structural characterization of an unseparated PNR bundle obtained from a BP flake through electrochemical Na-intercalation: (a) Low- and (b) high-magnification TEM image of a typical PNR bundle. (c) SAED of the same PNR bundle. Insets show the (002) diffraction spot having a clear arc form. (d) STEM image, (e) EDS phosphorous map, and (f) EDS spectrum of the same PNR bundle. (g) and (h) HRTEM images of such a PNR bundle. Sections of example PNRs and shown with blue straps, while the disordered region between two PNRs is shown using a pink strap.

FIGS. 2(a)-(l) are high and low magnification TEM images and corresponding SAED patterns of 4 Na-intercalated BP flakes, where FIGS. 2(a)(d)(g)(j) are a set of high magnification TEM images, FIGS. 2(b)(e)(h)(k) are a set of low magnification TEM images and FIGS. 2(c)(f)(i)(l) are the corresponding SAED pattern of the 4 Na-intercalated BP flakes.

FIGS. 3(a)-(c) are HRTEM images of exemplary PNRs made according to the described methods. The pseudo-colors are used to indicate crystalline nanorribons (blue) and amophous edges (red).

FIG. 4(a)-(c) are HRTEM images of a folded nanoribbon, with FIG. 4(a) showing the overall HRTEM image, FIG. 4(b) showing the enlarged side view of the nanoribbon, and FIG. 4(c) showing the enlarged top view of the nanoribbon with the arease marked in the dashed boxes in FIG. 4(a).

FIGS. 5(a)-(e) show tomic force microscopy (AFM) analysis of the produced nanoribbons. FIG. 5(a) AFM image of a streak of nanoribbons formed through drop-casting that is directed from lower-left to upper right. FIG. 5(b) Enlarged image within dashed box in FIG. 5(a) showing that the streak consists of many elongated entities consistent with nanoribbons. FIG. 5(c) Height-scan profile taken along the dashed-yellow line in FIG. 5(b). FIGS. 5(d-e) Thickness and length histogram analysis of 34 different elongated entities giving an average thickness of 5.4±2.5 nm and length of 300±90 nm.

FIG. 6 is a schematic which illustrates a conversion of BP flake (top) into an unseparated PNR bundle during electrochemical Na-intercalation.

FIGS. 7(a)-(h) illustrate characterization of PNRs obtained after sonication of Na-intercalated BP sample: FIG. 7(a) Low-magnification TEM image showing many PNRs on a support holey carbon film. FIGS. 7(b)-(e) HRTEM images of individual PNRs. Lattice fringes their corresponding d-spacing values are shown in insets. FIG. 7(f) Size distribution comparison of PNRs obtained. FIG. 7(g) A histogram of the aspect ratio of PNRs shown in FIG. 7(a). FIG. 7(h) Raman spectra from two regions of isolated PNRs. A Raman spectrum of BP flake is shown for comparison.

FIG. 8(a) is a graph presenting a statistical distribution of the lengths and widths of the as-synthesized PNRs obtained from TEM analysis.

FIG. 8(b) is a pair of TEM images of PNRs with several nanoribbons longer than 500 nm indicated with blue lines.

FIGS. 9(a)-(d) present data from an in-situ Raman study of the PNR formation. FIG. 9(a) In-situ raman electrochemical sodiation set-up and graphic of the mechanism of PNRs production. FIG. 9(b) Intensity color maps for in-situ raman spectra obtained at different times and degrees of sodiation using EC:PC electrolyte. FIG. 9(c) Voltage profile during electrochemically Na intercalation process in liquid electrolyte. FIG. 9(d) Comparison between the 6 raman spectra taken during the in-situ electrochemical experiment indicating the structural changes BP undergoes at the evolution of time. The 6 points labelled on discharge curve in FIG. 9(c) coincide with the time and voltages the spectra shown were taken.

FIGS. 10(a)-(c) illustrate an identified Raman spectra deconvolution. FIG. 10(a) Raman spectrum of the BP flake before intercalation. FIG. 10(b) Raman spectrum after the intercalation. In addition to BP peaks (originating from PNRs), there are several additional peaks coming from discorded RP-like regions between PNRs. Notice that the B_{2g} mode decreased significantly in agreement with the Raman data from exfoliated PNRs (see FIG. 7h). Note, that the B_{2g} in this sample can be overestimated because RP has a coincidental peak in the similar location (see FIG. 2(c)) FIG. 10(c) Raman spectrum of RP.

FIGS. 11(a)-(b) presents a schematic of a PNR formation mechanism which fits the data described herein, it being understood that the invention is not bound by this theory. The possible mechanism involves the strain relaxation between at a higher concentration of Na ions.

FIG. 12(a) is a graph with I_{DS}−V_{GS} curves for an unseparated bundle of PNR at V_{DS}=0.5V.

FIG. 12(b) is a graph with I_{DS}−V_{DS} curves for varying V_{GS} values from 0 to 4 V in 1 V steps.

FIG. 13 is a schematic of an optical micrograph and a schematic of a field effect transistor (FET) device structure, based on an unseperated bundle of PNRs.

### DETAILED DESCRIPTION

Phosphorene nanoribbons (PNRs) have inspired strong research interests to explore their exciting properties that associate with the unique 2D structure of phosphorene as well as the additional quantum confinement of the nanoribbon morphology, providing new materials strategy for electronic and optoelectronic applications. Despite several important discoveries, the production of PNRs with narrow widths was still a great challenge prior to this invention. In a particular aspect of the invention, a facile and straightforward approach is provided to synthesize PNRs via electrochemical process that utilize the anisotropic Na⁺ diffusion barrier in black phosphorus (BP) along the zigzag direction against the armchair direction. The produced PNRs display widths of good uniformity (10.3±3.8 nm) observed by high resolution transmission electronic microscopy (HR-TEM), and the suppressed B_{2g} vibrational mode from Raman spectroscopy results. More interesting, when used in field-effect transistors (FETs), synthesized bundles exhibit the n-type behavior, which is dramatically different from bulk BP flakes which are p-type. Aspects of this described synthesis approach of PNRs with confined width, allows for the development of phosphorene and other highly anisotropic nanoribbon materials for high quality electronic applications.

The impressive physics exhibited by graphene and its derivatives after its successful isolation in 2004 has sparked the strong interests of researchers in the development of novel two-dimensional (2D) layered materials and the subsequent exfoliation of their layers. While 2D materials confine charge carriers to a plane (electron motion is not confined in two dimensions with only one dimension quantized), one-dimensional (1D) structures, such as nanowires and nanoribbons (NRs), localize carriers in one more dimension (electron motion is not confined in one dimension with two dimensions quantized) which leads to additional unique properties, including higher mobility, strain tunable characteristics, high optical absorption, high density of states, enhanced excitation binding energy, improved surface scattering for electrons, etc. NRs also have high concentration of edge sites, which are often responsible for excellent catalytic performance and allow an easy functionalization and further tuning of properties toward high performance applications in fields such as energy storage, hydrogen generation, sensors, etc. The nanostructurig of 2D layered materials into 1D nanoribbons, not only results in significant redesigning of material's density of states and band structure but also creates a high-density of edge sites. These advanced features lead to interesting properties such as high catalytic activity and easy for functionalization, and open up lots of novel possibilities in a throng of applications.

Among a plethora of post-graphene 2D layered materials, phosphorene which is exfoliated from black phosphorous (BP) has been a subject of intense research since its maiden isolation in 2014. This is due to phosphorene's unique properties, including its high charge carrier mobility (2,000 cm² V⁻¹ s⁻¹), thickness-dependent bandgap (0.3−2.0 eV), and high in-plane anisotropy. Phosphorene degrades in hours by the combined action of moisture and oxygen upon exposure to ambient conditions because of reactive lone pair of electrons in P atoms. This has been a drawback to its device compliance in lots of applications. Strategies like encapsulation, surface passivation, surface functionalization and doping have been developed with varying degrees of success to help enhance the stability of phosphorene. Phosphorene starts degrading from the surface as oxygen molecules approach with an exothermic energy of −4.07 eV per molecule. Cutting phosphorene sheets into nanoribbons leaves highly active and unstable edges; thus, potentially leaving them chemically less stable than phosphorene sheets. Passivating PNRs edges with functional group like hydrogen could potentially improve its stability as observed in ab-initio calculations. Phosphorene nanoribbons (PNRs) display even more impressive properties (e.g. increase bandgap, modified electronic structure, higher density of states, etc.) due to quantum confinement effects, and high density of edge sites. PNRs have also been predicted to exude excellent properties like polarization dependent anisotropic response, exceptional mechanical properties, and highly active bonding sites. Quantum confinement and diminished dielectric screening causes excitons in atomically thin semiconductors like PNRs to exhibit binding energies an order of magnitude larger than their bulk counterpart. Consequently, they show high promise for applications in electronic devices, optics, magnetism and catalysis. Given their high exciton binding energies, tunable band gaps, solution-based processing, and very high carrier mobilities, PNRs are highly promising materials for optoelectronics. Recently, MacDonald et al. have demonstrated the potential of PNRs for photovoltaic applications. They have incorporated PNRs into perovskite solar cells and demonstrated improved efficiency of these devices due to the enhanced electrical transport between the light-absorbing perovskite layer and a semiconducting polymer. PNRs are also predicted to host several exotic states and may play an important role in several fundamental areas of condensed matter physics. In addition to topologically-protected edge states, some of the other exotic properties predicted for these structures include spin-density waves, strain-dependent antiferromagnetism, and half-metallic behavior which could be relevant to spintronics applications, the spin-dependent Seebeck effect, that could help to advance thermoelectric technologies, and a large singlet-triplet spitting, that could potentially be relevant to quantum information. The crossed Andreev reflection has also been recently investigated theoretically in structures based on such nanoribbons.

Starting in 2016, initial attempts of producing PNRs, such as etching, electro-beam sculpting and electro-beam lithography have been explored. However, these expensive and complicated approaches yielded nanoribbons with limited lengths and often stacked together. Only recently, more efficient and cost-effective top-down exfoliation approaches have been attempted towards the synthesis of PNRs. In 2019, Watts et al. produced high-quality PNRs by intercalating bulk BP with Li ions via a low-temperature, ammonia-based method, and then mechanically exfoliating Li-intercalated BP into nanoribbons in stable liquid dispersions. Although this method has been used by MacDonalds et al. to synthesize PNRs nanoribbons applied in photovoltaic devices, the cryogenic (−50° C.) processing requirements of this process make it costly and present a challenge for scalability. Subsequently, Liu et al. synthesized phosphorene nanobelts (PNBs) electrochemically in an oxygen assisted intercalation process. While the thickness of most of the belts produced was less than 3 nm, the impact of oxygen molecules at the edges of as-prepared PNBs is problematic. Yu et al. used a dual electrochemical set-up based on quaternary ammonium electrolyte to produce PNRs that had relatively higher aspect ratio (˜100) than those reported by Watts and Liu. However, majority of the widths of the ribbons produced were still in the micron scale. Very recently, Macewicz et al. complimented a chemical vapor transport (CVT) with mechanical exfoliation to produce larger BP nanoribbons and nanobelts that had a length-width ratio in a few hundred range (with width of 1.5 μm and length of 500 μm). Such larger dimensions may limit the active sites available for chemical bonding and modification.

Recently, we have reported that the electrochemical Li intercalation in BP was highly anisotropic, and the Li⁺ diffusion along the channels of the puckered structure of BP lattice led to the grove formation and segmentation of BP flakes into weakly connected nanoribbon-like strips along the zigzag direction. In addition, Kim et al. observed the anisotropic diffusional behaviors for both Li⁺ and Na⁺ that favorable zigzag direction of BP other than armchair direction, meanwhile, the diffusion barrier of Na⁺ along the armchair direction (268 meV) is apparently significantly larger than that of Li ions(156 meV).

Herein, it is shown that the anisotropic Na⁺ diffusion barrier in black phosphorus (BP) along [001] zigzag direction against [100] armchair direction provides the great chance to produce PNRs and the narrow stripes along zigzag direction induced by anisotropic Na intercalation can be the precursors to produce PNRs which show unique performance. In particular, it is demonstrated herein that a low-cost and feasible scalability two-step electrochemical method permits synthesizing PNRs with confined width (10.3±3.8 nm) and uniform length (250±156 nm), which is dramatically narrower than PNRs in most of the previous methods. In this two-step approach, BP flakes are firstly nanostructured through an electrochemical discharge process into bundles of parallel PNRs separated from each other by regions of highly disordered phosphorous, then followed by an ultrasonic treatment in DMF or other suitable solvent to separate the PNR bundles into individual and well-isolated PNRs. The produced PNRs show a significantly confined structure with the suppressed B2 g vibrational mode, as revealed by Raman spectroscopy. Furthermore, unlike in the case of phosphorene or BP devices, a field effect transistor (FET) prepared from a bundle of unseperated PNRs exhibits a typical n-type behavior.

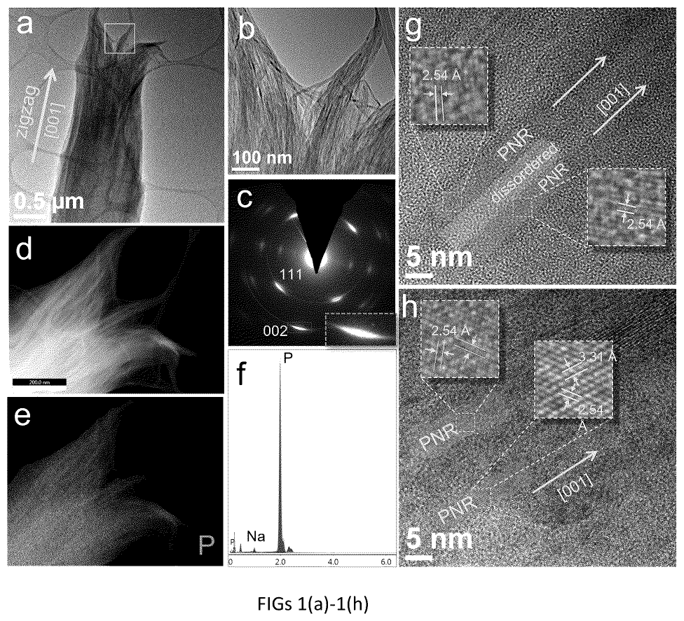

To obtain a better understanding of the inventive PNR fabrication method and to characterize the PNRs produced by this method, a detailed structural and elemental analysis was conducted before and after the ultrasonication step, i.e., after the PNRs were separated from each other. For these measurements, the obtained samples were dispersed in DMF, drop-casted on holey carbon-on-copper grids, and analyzed using transmission electron microscopy (TEM). A representative set of the data from the obtained BP sample after electrochemical intercalation is shown in FIGS. 1a-h.

FIG. 1a-b show a low- and high-magnification TEM image of a typical unseparated bundle of PNRs, respectively. The brush-like morphology of the bundle is the result of nearly parallel PNRs separated one from each other by narrow columnar regions of highly disordered phase. Selected-area electron diffraction (SAED) was used to analyze the crystallinity of the PNRs located between these amorphous regions. The SAED pattern of the bundle shown in FIG. 1a-b is presented in FIG. 1c. The strongest diffraction reflections visible in this pattern are the (00±2) and (±1±11) reflections of BP. However, instead of sharp diffraction spots, these reflections are seen as arcs due to slight deviations of PNRs from being exactly parallel to each other. Nevertheless, from the comparison between TEM images and the corresponding SAED patterns it was determined that PNRs are parallel to their (i.e., zigzag) crystallographic direction.

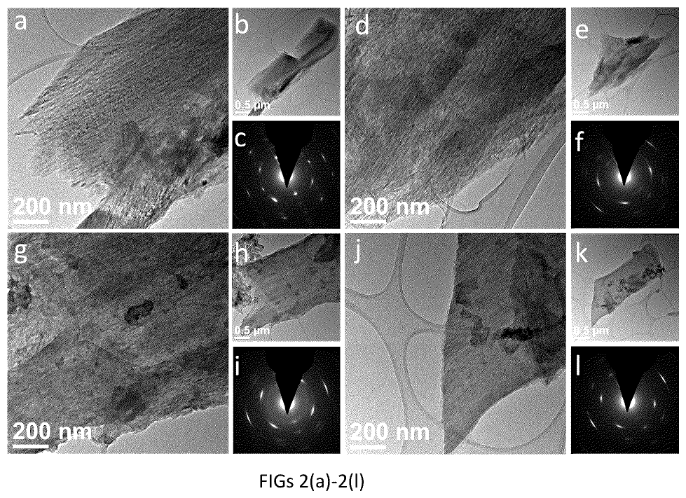

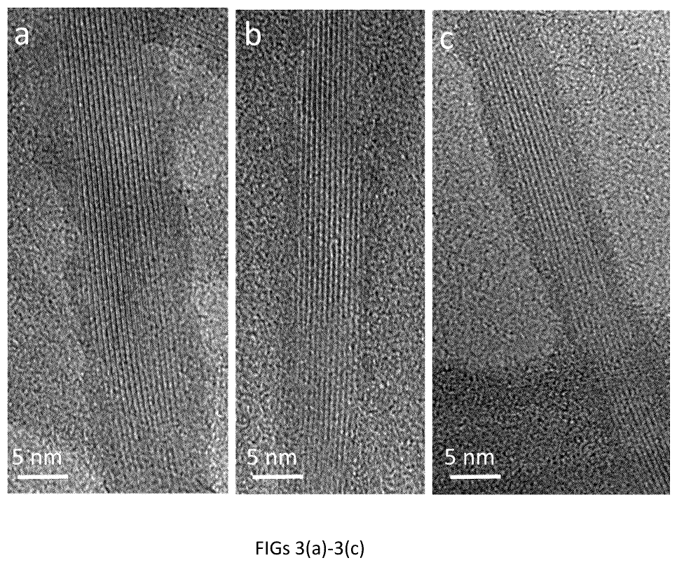

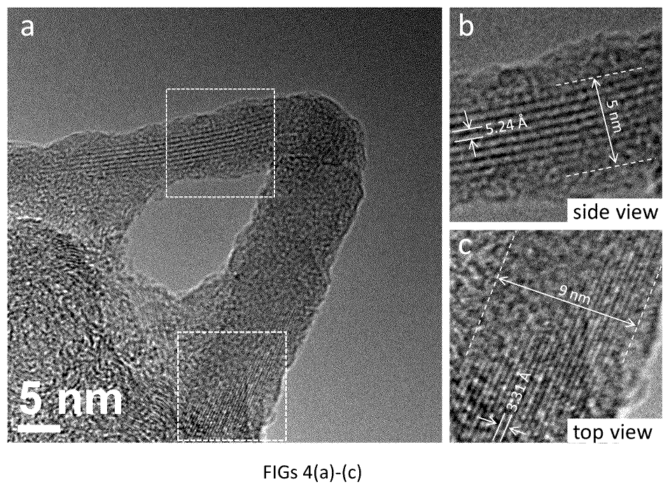

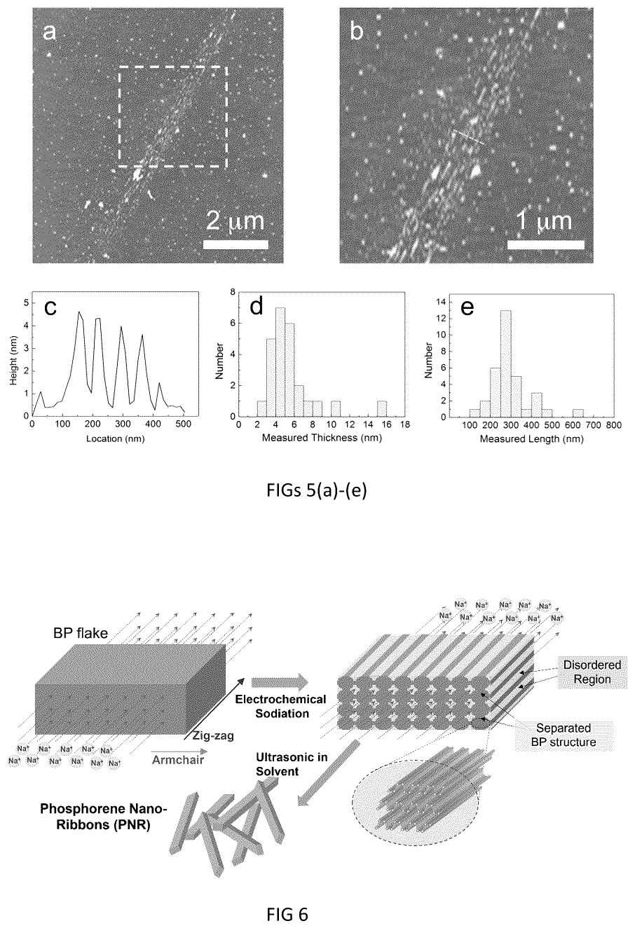

The majority of Na-intercalated BP flakes observed in TEM had the morphology of unseparated bundles of PNRs, as shown in a few examples included in FIGS. 2a-1. The edges of the PNRs obtained in using the described processes are terminated with an amorphous layer as shown in FIGS. 3a-c which could help to passivate the edges and improve stability. The nanoribbons produced by this method are in the few nm thickness range as indicated from HRTEM images shown in FIGS. 4a-c and AFM shown in FIG. 5a-e. In performing the AFM analysis, focusing was on a relatively thin drop-cast streak shown in FIG. 5a. Enlarging this region in FIG. 5b shows that the streak is comprised of an accumulation of elongated features, which are the phosphorene nanoribbons. The height profile in FIG. 5c along the yellow line in FIG. 5b shows that these elongated nanoribbons have a thickness of roughly 4 nm. Using such height profiles, analysis was performed on 34 different nanoribbons for this sample and the distributions of thickness and length were obtained, as shown in FIG. 5d and FIG. 5e. Using these data, the thickness of the nanoribbons in this sample is computed to be 5.4±2.5 nm while the length is computed to be 300±90 nm. These values for the thickness and length of the nanoribbons are consistent with the results obtained through the TEM analysis.

Returning to the data in FIGS. 1a-h, elemental analysis using energy dispersive X-ray spectroscopy (EDS) confirmed that PNRs contained mainly phosphorous. This is evident from the elemental mapping (FIG. 1e) and EDS spectrum (FIG. 1f) of the bundle shown in FIG. 1a-b. The HAADF-STEM image corresponding to the phosphorous map in FIG. 1e is shown in FIG. 1d. The traces of Na apparent in the EDS spectrum (FIG. 1f) are most likely from the highly disordered regions between the PNRs. Since the cut off voltage is very low at 0.1 V to achieve full discharge, the reductive products such as NaₓP are expected (at least in the disordered region). However, the weak line of Na in the EDS spectrum suggests that the formed NaₓP compounds are probably dissolved in liquid electrolyte.

As discussed above, the crystalline nature of PNRs was also confirmed using high-resolution TEM (HRTEM). The PNRs showing crystalline lattice fringes were observed separated from each other by regions of disordered phase. Example HRTEM images from the PNR bundle analyzed in FIG. 1a-f are shown in FIG. 1g-h. The d-spacing values obtained from the visible lattice fringes were found to be 2.54 Å and 3.31 Å, which agreed with the d-spacing values expected for PNRs viewed along the zone axis.

The nanoribbons were produced by anisotropic intercalation of Na into BP as shown in the model in FIG. 6. First, Na⁺ were electrochemically driven into BP layers. Due to a very strong anisotropy of the diffusion coefficient, Na preferentially move along the zigzag direction of BP which has longer bond-length of 2.244 Å. Other than along the armchair direction where Na⁺ have a high diffusion barrier of 268 meV, while Na diffusion along the zigzag direction has a low energy barrier of 93 meV. Such a huge difference is the driving force behind the anisotropic diffusion behavior, resulting in the zigzag-oriented intercalation channels during sodiation process. On the other hand, the large diffusion barrier of Na along the armchair direction leads to a well-defined columnar intercalation of Na in BP, resulting in the long [001]-oriented columns of disordered material, as schematically shown in FIG. 6.

The observed mechanism is similar to the mechanism behind the production of PNRs via Li intercalation driven ionic scissoring described by Watts et al. However, the intercalation in the present work is driven electrochemically and not Li but Na ions are intercalated. In the Li⁺ induced process presented by Watts et al., the formation of PNRs is explained by a charge transfer and electron doping which increases over time and eventually causes the bond breaking (or cutting) along the diffusion path. A similar mechanism may take place in our case of electrochemical insertion of Na⁺ ions.

Layered materials are typically etched or patterned along a specific direction to form 1D strips as seen in graphene and MoS₂ nanoribbons. The relatively large size of Na⁺ (227 pm) causes the strain and distortion of BP lattice that accumulates during electrochemical intercalation and eventually leads to relaxation and the formation of nanoribbons separated from each other by disordered columnar regions, as shown schematically in FIG. 6. This observation is similar to the reported disordered stripes seen by Cheng et al. They attributed the amorphization of BP by sodium-induced reordering of atomic stacks to the breaking of P—P bonds and lattice constraints.

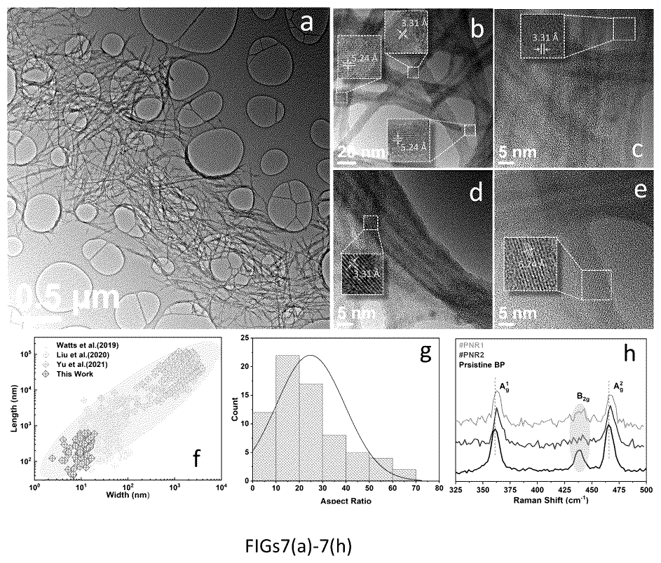

The sonication of the parallel bundle of BP sample after electrochemically intercalation was performed to separate the PNRs, which were then analyzed by HRTEM and Raman spectroscopy. FIG. 7a shows the exfoliated PNRs deposited on holey carbon-on-copper grids. The d-spacing of representative PNRs were measured from HRTEM images shown in FIGS. 7b-e. Due to the random distribution of PNRs after exfoliation and their occasional twisting, PNRs seen from the top (i.e., along the zone axis) and from the side (i.e., along the direction) can be found in these images, as indicated by the measured d-spacing values of 3.31 Å and 5.24 Å, corresponding to (100) and (020) planes, respectively.

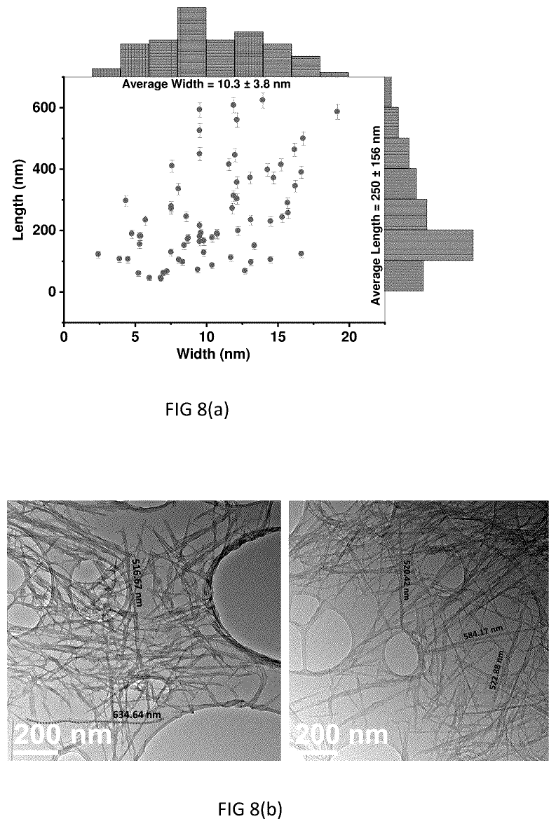

FIG. 8(a) presents the size distribution of the synthesized PNRs and FIG. 8(b) shows two exemplary TEM analyses. Compared to prior research (see FIG. 7(f)) the PNRs produced using the methods described herein are obviously smaller in dimensions with thin widths (10.3±3.8 nm) and short lengths (250±156 nm). With such small dimensions, the produced nanoribbons are able to possess more active sites at their edges and enhanced quantum confinement effects. This behavior has been observed in graphene nanoribbons (GNRs) as they display a finite bandgap when the widths below 10 nm. Notably, the produced PNRs display the narrowest widths in comparison with other methods, as seen in FIG. 7f. Moreover, the shown data in FIG. 7f display a clear trend, suggesting that the aspect ratio for PNRs remains approximately constant in a wide range of length (10¹-10⁵ nm). The vibrational modes and Raman peaks of as-synthesized PNRs in this work are blue-shifted (FIG. 7h), with the suppressed B_{2g} peak, which is in good agreement with the observation by MacDonald et al. Pristine BP had peak positions for A_{g}¹, B_{2g} and A_{g}² phonons respectively at 361.3, 438.2 and 466.1 cm⁻¹ while the PNRs only showed the peak positions for A_{g}¹, and A_{g}² phonons at 363.0˜363·cm⁻¹ and 467.2˜467.5 cm⁻¹, respectively. The blue shift of A_{g}¹/A_{g}² and the suppressed B_{2g} peak observed in the synthesized PNRs was due to the decrease in thickness and dimensionality.

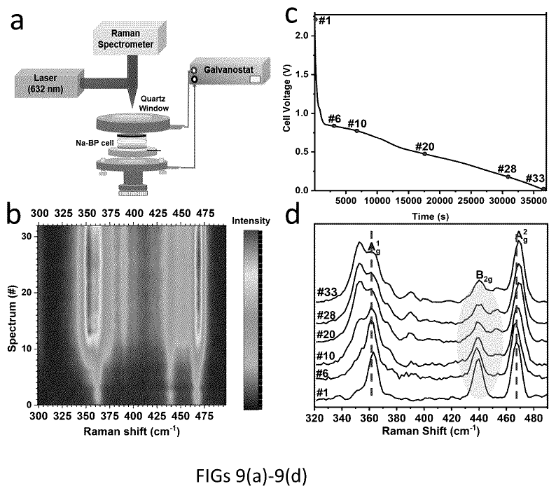

To gain a better understanding of the mechanism of the electrochemical induced PNRs formation in BP, in-situ Raman spectroscopy was performed (FIG. 9a) as it closely tracks the real-time structural change of BP flake during the intercalation of Na⁺ in the EC/PC electrolyte environment. FIG. 9b represents the spectra stack of BP taken at different intercalation levels using a dedicated electrochemistry in-situ Raman cell set. Downshifting of the active was observed with Raman phonons of BP: A_{g}¹ (out of plane armchair direction, ˜360 cm⁻¹), B_{2g} (in-plane zigzag direction, ˜437 cm⁻¹) and A_{g}² (in-plane armchair direction, ˜464 cm⁻¹) up to the intercalation time of ˜15,000 s (voltage >0.55 V) as A_{g}² and B_{2g} phonons moved faster than A_{g}¹. This observation corresponds to the Na intercalation behavior that the structure of BP is preserved while the interlayer gap is disordered. Further sodiation beyond ˜15,000 s caused A_{g}¹ and B_{2g} phonon modes to exhibit satellite peaks at around ˜372 cm^{31 1} and ˜445 cm⁻¹, respectively (FIG. 9b), which may attributed to the structural disorder along the zigzag direction in the area between nanoribbons. The in-situ Raman spectra of six discharge times on the discharge curve (FIG. 9c) are shown in FIG. 9d, which clearly display the structural evolution of BP from selected spectra (#1, #6, #10, #20, #28, and #33).

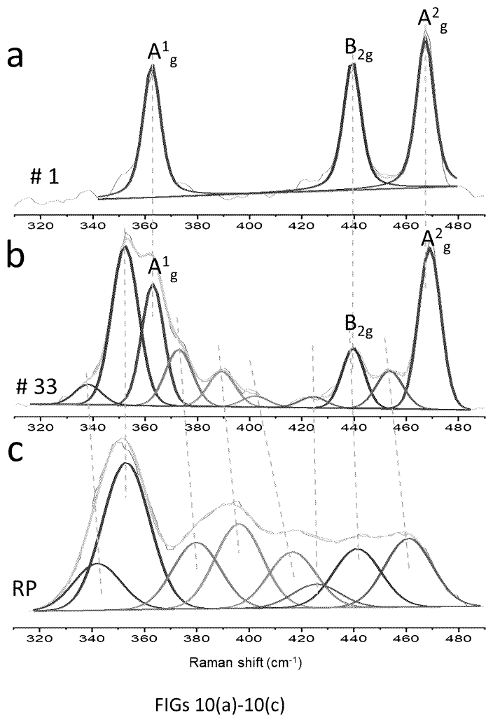

Spectra #1 (i.e., before the Na intercalation) and #33 (i.e., after the Na intercalation) were deconvoluted using the Lorentzian function, as shown in FIGS. 10a-c. It is observed that spectrum 33 exhibited the signature modes of BP (A_{g}¹, A_{g}², and weak B_{2g}) and the remaining peaks closely resembled the peaks of red phosphorous (RP), as indicted by the comparison with the spectrum of RP (FIG. 10c). This strengthens the possibility of the partial disordering of BP structure due to lattice distortion as Na intercalation proceeded. Mitrovic et al. have reported the partial disordering of BP intercalation compounds (BPIC) into RP by diazonium salts. They found that the formation of amorphous phase in the reaction was facilitated by high concentration of intercalants (Na or K). Furthermore, the Raman spectra of the final product clearly exhibited peaks signature to BP and RP. Abellan et al. also observed Raman peak splitting, formation of new peaks and ribbons as they synthesized black phosphorous intercalation compounds (BPICs) with Na and other alkali metals. They linked these outcomes to breaking of P—P bonds as intercalant atoms increased in BP sheets. Interestingly, additional Raman peaks observed by Watts et al. were attributed to symmetry distortions at the edges of as-synthesized PNRs. Reordering of atoms around the edges of the nanoribbons and changes in the movement of atoms linked to the signature Raman modes causes the appearance of additional Raman tensor elements.

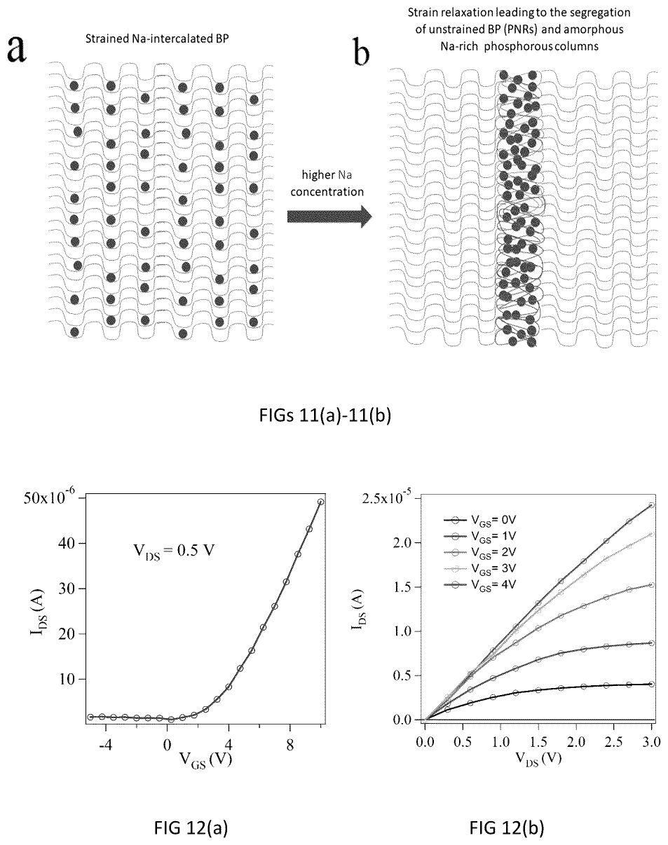

The combined TEM and Raman results indicate there is a threshold of Na concentration and build-in strain up to which the Na-intercalated BP has a homogenous, single-phase structure (FIGS. 11a). At higher concentration of Na ions above the threshold, a strain relaxation takes place, which leads to the phase segregation and alternating regions of unstrained BP (PNRs) and disordered phosphorous regions reach in Na (FIG. 11b).

Previous systematic studies on the intercalation of BP with Li have shown different outcomes. The mechanism of intercalation of BP with Li ions as observed through Raman measurements is significantly different as B_{2g} and A_{g}² phonon modes steadily downshift 1.6 times faster than A_{g}¹ with the intensity of successive spectrum decreasing. The discrepancy in the behavior of the Raman spectra of BP under Na⁺ and Li⁺ intercalation influences is due the restriction of Na⁺ diffusion along the [100] armchair direction, which gives rise to columnar intercalation along the [001] zigzag direction.

In FIGS. 12a-b the electrical properties of a back-gated FET based on an unseparated bundle of PNRs placed between aluminum source/drain with electrostatic electron-doping by a back-gate are presented. As shown in FIG. 12a, we supplied a fixed bias of 0.5 V between the source and the drain and swept the gate voltage from −5 to 10 V. The results demonstrate that the device state switched from ‘off’ to ‘on’ state with a current increase up to several orders for positive gate source bias (V_{GS}) values. The measured transfer characteristics showing an increase of the current values when the gate voltage became increasingly positive is characteristic of the typical behavior of a n-type FET due to the accumulation of the majority electron in a n-type material at positive gate voltages. FIG. 12b shows drain source current (I_{DS}) vs drain source voltage (V_{DS}) curves for varying V_{GS} values from 0 to 4 V in 1 V steps. As expected, I_{DS} increases with V_{GS} up to a certain point and becoming almost constant (plateau) as V_{GS} increases beyond that point. Normally, BP and black arsenic-phosphorous (b-AsₓP₁₋ₓ) alloys are typical p-type materials, and FET devices made out of thin layers of phosphorene, as well as thick flakes of BP show typical p-type characteristics. Therefore, the n-type behavior measured for our device is a direct evidence of the effective charge transfer and n-type doping due to the Na intercalation into the structure.

### EXAMPLE

The above description provides a simple and feasible two-step electrochemcial intercalaction method to produce PNRs with narrow widths of good uniformity (e.g., 10.3±3.8 nm). The prepared narrow PNRs show zigzag direction as well as the suppressed B_{2g} Raman mode. Interestingly, the FET device structure prepared from a bundle of PNRs showed the n-type transistor behavior due to the effective charge transfer and n-type doping induced by sodium intercalation. This new synthesis approach of PNRs with confined width permits the development of phosphorene and other highly anisotropic nanoribbon materials for high quality applications. The methods used for the above description are as follows:

### Methods

Bulk BP was produced by means of chemical vapor transport growth method from red phosphorous (500 mg, Sigma, >97%) while Sn (20 mg, Alfa Aesar, 99.8%) and SnI₄ (20 mg, Alfa Aesar, 95%) served as mineralization agents. The precursors were carefully measured into a quartz ampoule that was sealed at a vacuum of 10⁻⁶ Torr. At a temperature gradient of 50° C., the sealed ampoule was annealed at 615° C. in two-zone furnace and precursors were placed at the hot end. Exhaustive steps for this process have been provided.

Electrochemical Na intercalation of BP was achieved in coin cells that were prepared with BP and Na metal as a cathode and an anode, respectively. Cathode pastes were prepared with the weight of the BP and carbon binder in the ratio 1:2, then the pastes were put on stainless steel mesh (diameter 18 mm) and dried under vacuum at 150° C. for 3 hours. The Na intercalation process was performed in liquid electrolyte medium that containing a mixture of 1 M of NaPF₆ with a binary solution of ethylene carbonate: propylene carbonate (EC:PC). The cut-off voltage was set to 0.1 V under a current density of 30 μA cm⁻². After the electrochemical intercalation step, the coin cell was opened in an inert atmosphere (e.g. a glovebox) and the cathode was cleaned using dimethylformamide (DMF).

A dedicated electrochemical split cell with a quartz window manufactured by MTI Corporation was used for this experiment (FIG. 9a). For the cathode, a similar weight ratio of BP to carbon binder used for the coin cells was adapted, and then ground to homogeneity. The paste was then placed on a stainless-steel mesh to further enhance charge transfer and dried for 3 hours at 150° C. NaPF₆ in EC:PC was used as electrolyte. The cell assembly was carefully carried out in an argon filled glovebox with both moisture and oxygen level less 5 ppm. After cycling was complete, the coin cells were taken apart in an argon-filled glovebox and some of the cathode pastes was dispersed in a vial containing 2 ml of DMF. The vial was tightly closed and further made airtight with layers of parafilm. The vial was then sonicated for 10 minutes to clean off binder and separate bundles of PNRs into individual nanoribbons.

Atomic force microscopy (AFM) imaging was performed using an Asylum Research MFP-3D in AC-mode. Images were ElectriTap300-G, a tapping mode AFM probe with a platinum overall coating (force constant 40 N/m, resonant frequency 300 kHz, and a tip thickness of 4 μm) (Budgetsensors). All images were collected and processed (flattened and plane-fit) using IgorPro software. Sample preparation for the AFM measurements was performed in a dry nitrogen glove-box. A drop of a suspension of phosphorene nanoribbons in DMF was drop cast onto an SiO₂ surface located on ˜5 mm square Si substrate. The drop was allowed to evaporate in the glove-box, leaving the residual solids from the suspension bound to the SiO₂ surface. The residual solids form into random arrangements of blotches and streaks of various thicknesses.

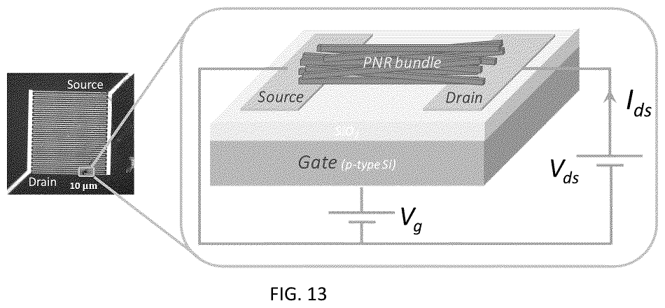

An unseperated bundle of PNRs was used to fabricate a field effect transistor (FET) device structure, such as the one shown schematically in FIG. 13. The aluminum contacts of the interdigitated contact pattern serve as the source and the drain of the FET device while the p-doped Si serves as the back gate. Electrical measurements were carried out using a Keithley 6487 picoammeter/voltage source which has the current resolution of 10 fA and a Keithley 2400 source-measure unit to supply the gate voltage.

Statistical Analysis:

Using TEM images and AFM height profiles, we analyzed 71 and 34 different nanoribbons, respectively. The distribution of width, length, and thickness or the nanoribbons was obtained. This data was also used to calculate the average values and standard deviations. These values obtained from the AFM measurements are consistent with the results obtained through the TEM analysis.

1. A phosphorene nanoribbon having a length ranging from 1 nm to 10,000 nm and a width ranging from 1 nm to 20 nm.

2. The phosphorene nanoribbon of claim 1 wherein the width ranges from 1 nm to 15 nm.

3. The phosphorene nanoribbon of claim 1 wherein the width ranges from 1 nm to 10 nm.

4. The phosphorene nanoribbon of claim 1 wherein the width ranges from 7-15 nm.

5. The phosphorene nanoribbon of claim 1 wherein the phosphorene nanoribbon is of uniform dimensions.

6. The phosphorene nanoribbon of claim 1 wherein the length ranges from 50 nm to 5000 nm.

7. A Field Effect Transistor comprising one or more phosphorene nanoribbons, or a bundle of phosphorene nanoribbons, where the one or more phosphorene nanoribbons or the bundle of phosphorene nanoribbons exhibit n-type behavior.

8. A method of making nanoribbons, comprising:
nanostructuring one or more flakes or grains of highly anisotropic layered material using an electrochemical process of insertion of ions to produce bundles of nanoribbons separated from each other by regions of disordered materials; and
ultrasonically treating the bundles of nanoribbons in a solvent medium in order to separate the bundles of nanoribbons into a plurality of separate nanoribbons.

9. The method of claim 8 wherein the highly anisotropic layered material is highly anisotropic layered van der Waals material.

10. The method of claim 8 wherein the highly anisotropic layered material is a layered material of group V-element, a layered alloy of group V-elements, a layered material of group-IV monochalcogenides, or a layered alloy of group-IV monochalcogenides.

11. The method of claim 8 wherein the highly anisotropic layered material is a layered material with a puckered honeycomb structure.

12. The method of claim 8 wherein the highly anisotropic layered material is a layered arsenic-phosphorous alloyed material, wherein the relative molar concertation of arsenic to phosphorous is between 0 and 1.

13. The method of claim 8 wherein the highly anisotropic layered material is a black phosphorous.

14. The method of claim 8 wherein each of the plurality of separate nanoribbons have a length ranging from 1 nm to 10000 nm and a width ranging from 1 nm to 100 nm.

15. The method of claim 8 wherein the bundles of nanoribbons produced in the nanostructuring step include a plurality of parallel nanoribbons separates by the regions of disordered material.

16. The method of claim 8 wherein the nanostructuring step includes intercalating sodium or other cationic ions into the one or more flakes and grains of highly layered material to form the regions of disordered material, and wherein individual nanoribbons of the bundles of nanoribbons are comprised of predominantly crystalline material.

17. The method of claim 8 wherein the step of separating is performed by sonication of the one or more flake or grain entities in the presence of a solvent.

18. The method of claim 17 wherein the solvent is dimethyl formamide.

19. The method of claim 16 wherein the step of intercalating is performed under electrochemical process for insertion of ions.

20. A method of making phosphorene nanoribbons, comprising:
nanostructuring one or more black phosphorus flakes or grains using an electrochemical discharge process to produce bundles of phosphorene nanoribbons separated from each other by regions of disordered phosphorous; and
ultrasonically treating the bundlers of phosphorene nanoribbons while in a solvent in order to separate the bundles of phosphorene nanoribbons into a plurality of separate phosphorene nanoribbons.

21. The method of claim 20 wherein each of the plurality of separate phosphorene nanoribbons have a length ranging from 1 nm to 5000 nm and a width ranging from 1 nm to 20 nm.

22. The method of claim 20 wherein the bundles of phosphorene nanoribbons produced in the nanostructuring step include a plurality of parallel phosphorene nanoribbons separated by the regions of disordered phosphorous.

23. The method of claim 20 wherein the nanostructuring step includes intercalating sodium or other ions into the one or more black phosporous flakes or grains to form the regions of disordered phosphorous, and wherein individual phosphorene nanoribbons of the bundles of phosphorene nanoribbons are comprised of predominantly crystalline phosphorous.

24. A method of making phosphorene nanoribbons, comprising:
intercalating sodium or other ions into one or more black phosphorous flakes or grains along a zig-zag direction of the one or more black phosprous flakes or grains to produce one or more black phosphorous flake or grain entities which include a plurality of parallel crystalline phosphorous regions separated by a plurality of sodium or other ion containing disordered phosporous regions; and
separating the plurality of parallel crystalline phosphorous regions from each other in the one or more black phosporous flake or grain entities and removing the plurality of sodium or other ion containing disordered phosphorous regions to produce a plurality of phosphorene nanoribbons.

25. The method of claim 24 wherein the step of separating is performed by sonication of the one or more black phosporous flake or grain entities in the presence of a solvent.

26. The method of claim 25 wherein the solvent is dimethyl formamide.

27. The method of claim 24 wherein the step of intercalating is performed under electrochemical discharge.

28. The method of claim 24 wherein each of the plurality of separate phosphorene nanoribbons have a length ranging from 1 nm to 5,000 nm and a width ranging from 1 nm to 20 nm.
